(19) United States
(12) Patent Application Publication
(10) Pub. No.: US 2007/0235213 A1
(43) Pub. Date: Oct. 11, 2007

(54) 2-Layer printed circuit board and method of manufacturing the same

(75) Inventors: Chang Ik Lee, Suwon City (KR); Jun Cheol Dark, Osan City (KR); Dong Ryun Mok, Osan City (KR)

Correspondence Address: BIRCH STEWART KOLASCH & BIRCH, PO BOX 747, FALLS CHURCH, VA, 22040-0747, US

(73) Assignee: LG Electronics Inc.

(21) Appl. No.: 11/524,378

(22) Filed: Sep. 21, 2006

(30) Foreign Application Priority Data
Apr. 10, 2006 (KR) 2006-0032490

(51) Int. Cl. H05K 1/03

(52) U.S. Cl. 174/255

(57) ABSTRACT

The present invention relates to a 2-layer printed circuit board (PCB) for enabling impedance matching of a high frequency signal line, and a method of manufacturing the 2-layer PCB. In the present invention, an insulation layer with a predetermined thickness is formed as an insulation substance on a top surface of a signal layer formed on a general 2-layer PCB so as to protect a high frequency signal line formed on the signal layer. An auxiliary layer selectively including carbon, a PCB, a tape in the form of copper foil or the like is formed on a top surface of the insulation layer. At this time, the thickness of the insulation layer is determined to be different depending on a material of the auxiliary layer. Further, the auxiliary layer and a ground layer provided to the 2-layer PCB are electrically connected to each other. Then, the auxiliary layer serves as a ground plane. Accordingly, the present invention has an advantage in that impedance matching of a high frequency signal line is possible even in a PCB having a 2-layer structure and the manufacturing costs of a PCB can be reduced by simplifying a laminated structure.

### BACKGROUND OF THE INVENTION

1. Field of the Invention

The present invention relates to a printed circuit board (PCB), and more particularly, to a 2-layer PCB for enabling impedance matching of a high frequency signal line even in a PCB having a 2-layer structure, and a method of manufacturing the same.

2. Description of the Related Art

As is generally known, impedance matching is to prevent a distortion effect of a signal by reducing signal reflection caused from an impedance difference between two different connection ends when difference devices are connected to each other.

Characteristic impedance for the impedance matching is provided to most circuits. In the characteristic impedance, 50Ω is applied to a circuit and 75Ω is applied to an antenna. The characteristic impedance is also provided as reference impedance of a circuit or system. Since the reference impedance is provided, it is unnecessary to perform impedance matching whenever different devices are connected to each other.

FIG. 1 shows a configuration in which a DVD/recorder is connected to a TV device for the purpose of describing such impedance matching.

As shown in this figure, a DVD/recorder 1 is configured such that reproduced video/audio signals are transmitted to a TV 5 using a High Definition Multimedia Interface (hereinafter, referred to as HDMI) cable 7.

The DVD/recorder 1 is provided with an MPEG 2 for decoding video and audio signals with a reproduced digital signal as an input, an HDMI IC (Integrated Circuit) 3 for processing the video and audio signals received from the MPEG 2, and an HDMI jack 4 for transmitting the video and audio signals to an HDMI jack 6 for reception of the TV 5. A filter 9 (see FIG. 2) for eliminating a noise or the like is mounted to a front end of the HDMI jack 4 for transmission.

To reduce a loss caused from the distortion of a signal, a high frequency signal line 8 formed between the HDMI IC 3 and the HDMI jack 4 for transmission should match the characteristic impedance with impedances of the HDMI cable 7 and the HDMI jack 6 for transmission of the TV 5. The impedance of the HDMI cable 7 and the HDMI jack 6 for transmission of the TV 5 is provided as 50Ω.

Accordingly, for the impedance matching, the high frequency signal line 8 is generally formed as a laminated structure of a 4-layer PCB formed as shown in FIG. 2.

The laminated structure is provided in the form of a PCB between the HDMI IC 3 and the HDMI jack 4 for transmission. Eight high frequency signal lines are formed on the PCB, and each of the lines is formed as a 4-layer laminated structure. For reference, an 8-channel digital signal is supported to the high frequency signal line such that uncompressed full audio/video signals can be transmitted.

In the 4-layer laminated structure, a ground layer 11 (Ground, 0.036 mm) serving as a ground and a power source layer 12 (VCC, 0.036 mm) for power supply are formed on both surfaces of a core layer 10 (0.8 mm) made of an insulator, respectively. An insulation layer 13 (0.35 mm) and an upper signal layer 15 (0.04 mm) provided with a signal line are sequentially formed on a top surface of the ground layer 11, and an insulation layer 14 and a lower signal layer 16 (0.04 mm) provided with a signal line are also formed sequentially on a bottom surface of the power source layer 12.

At this time, the reason why the insulation layer 13 is designed just beneath the upper signal layer 15 is for the purpose of minimizing signal distortion when the audio/video signals are transmitted. Thus, for impedance matching, the thickness of the insulation layer 13 should be maintained to be 0.35 mm. That is, the thickness of 0.35 mm is a value at which a characteristic impedance of 50Ω can be provided. In other words, in order to match the PCB to the characteristic impedance of 50Ω, a mutual distance between the upper signal layer 15 and the ground layer 11 should be maintained to be about 0.35 mm.

However, in a case where the PCB is designed as the 4-layer laminated structure in such a manner, a material cost due to the multilayered structure is increased. This results in a manufacturing cost increase of products, so that weakening of competitive power is caused.

Accordingly, a PCB has been designed through a 2-layer laminated structure instead of the aforementioned 4-layer laminated structure.

FIG. 3 shows a laminated structure of a conventional 2-layer PCB applied to the inside of the DVD/recorder 1 shown in FIG. 1.

As shown in the figure, the 2-layer PCB is provided with a signal layer 20 (Signal, 0.04 mm) having a signal line for transmitting a high frequency signal formed thereon and a ground layer 21 (0.04 mm) for power supply interruption and heat dissipating operation, and a core layer 22 made of an insulator is formed to minimize signal distortion between the signal and ground layers 20 and 21. At this time, the thickness of the core layer 22 cannot but become 1.52 mm or more due to the physical structure of the PCB. That is, when the PCB is manufactured to have the 2-layer laminated structure, it should be manufactured in the same thickness as the entire thickness of the 4-layer laminated structure and in a thickness offset by the thickness of the signal and ground layers 20 and 21. Thus, since a space of 0.35 mm for impedance matching cannot be maintained, the impedance matching is impossible due to an increase of impedance.

Accordingly, the characteristic impedance is 160Ω or so in the 2-layer laminated structure, which generates a signal distortion phenomenon. The signal distortion phenomenon appears as shown in portion “A” of FIG. 4. Consequently, the signal distortion phenomenon becomes a factor of deteriorating performance of products.

### SUMMARY OF THE INVENTION

Accordingly, the present invention is conceived to solve the aforementioned problems. An object of the present invention is to provide a 2-layer PCB for enabling impedance matching of a high frequency signal line even in a PCB having a 2-layer structure and a method of manufacturing the same.

Another object of the present invention is to provide a 2-layer PCB for reducing manufacturing costs by simplifying a laminated structure and a method of manufacturing the same.

According to an aspect of the present invention for achieving the object, there is provided a 2-layer printed circuit board (PCB), comprising: a core layer made of insulator; a signal layer formed on a top surface of the core layer and provided with a high frequency signal line; a ground layer formed on a bottom surface of the core layer; an insulation layer formed in a predetermined thickness on a top surface of the signal layer; and an auxiliary layer formed on a top surface of the insulation layer for impedance matching of the high frequency signal line provided in the signal layer, the auxiliary layer being electrically connected to the ground layer.

Preferably, the thickness of the insulation layer is determined depending on the kind of substance constituting the auxiliary layer or depending on characteristic impedance of the high frequency signal line, and the characteristic impedance is 50Ω.

The auxiliary layer may be formed only in a region of the high frequency signal line, and any one of a liquefied carbon substance, a PCB and a tape in the form of copper foil may be applied. Further, it is preferred that the thickness of the insulation layer be formed to be 0.01 mm in a case of the auxiliary layer is the liquefied carbon substance.

The insulation layer may be coated with a liquefied solder resist.

According to another aspect of the present invention, a method of manufacturing a 2-layer PCB, comprising: forming a signal layer provided with a high frequency signal line and a ground layer serving as a ground on top and bottom surfaces of a core layer made of an insulator, respectively; forming an insulation layer on a top surface of the signal layer; forming an auxiliary layer on a top surface of the insulation layer; and connecting the auxiliary and ground layers electrically to each other, wherein the auxiliary layer is formed only in a region of the high frequency signal line provided in the signal layer.

Preferably, the thickness of the insulation layer is determined depending on the kind of substance constituting the auxiliary layer or depending on a characteristic impedance value of the high frequency signal line.

The characteristic impedance value may be variable.

A liquefied carbon substance, a PCB, a tape in the form of copper foil or the like may be selectively provided to the auxiliary layer.

Preferably, the insulation layer is formed to have a thickness of 0.01 mm for impedance matching of a high frequency signal line of the signal line when the auxiliary layer is made of a liquefied carbon substance. A liquefied solder resist with an insulative property may be applied on the insulation layer.

According to the present invention with such a configuration, impedance matching of a high frequency signal line becomes possible even in a PCB having a 2-layer laminated structure, so that uncompressed digital audio/video signals can be transmitted without signal distortion.

### BRIEF DESCRIPTION OF THE DRAWINGS

The above and other objects, features and advantages of the present invention will become apparent from the following description of a preferred embodiment given in conjunction with the accompanying drawings, in which:

FIG. 1 is a view showing a configuration of an example in which a DVD/recorder is connected to a TV device;

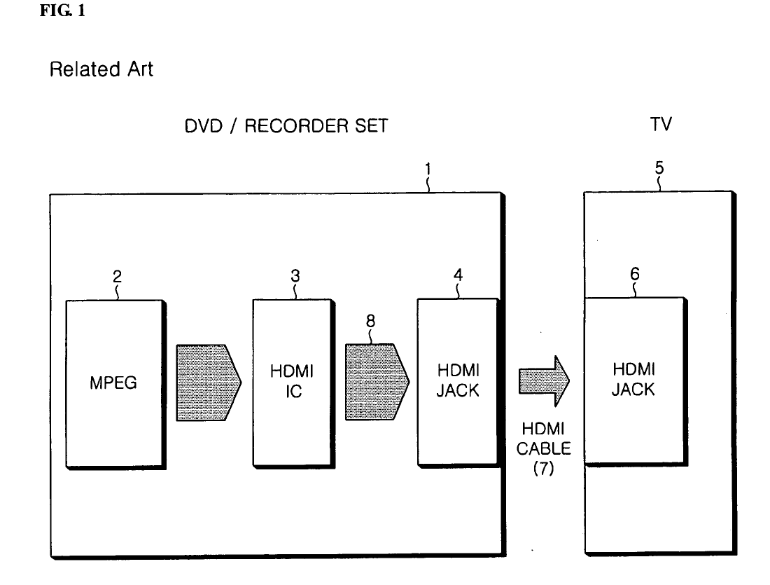

FIG. 2 is a view showing a laminated structure of a conventional 4-layer printed circuit board (PCB) applied to the inside of the DVD/recorder shown in FIG. 1;

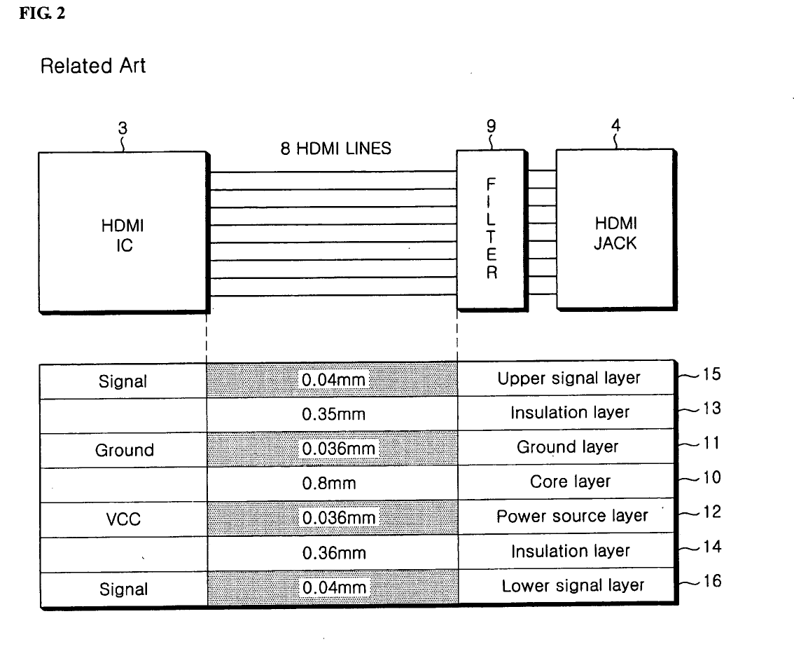

FIG. 3 is a view showing a laminated structure of a conventional 2-layer PCB applied to the inside of the DVD/recorder shown in FIG. 1;

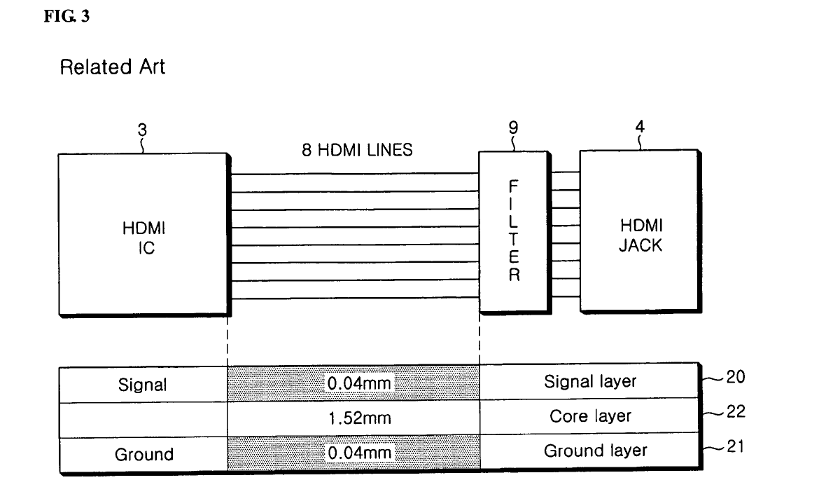

FIG. 4 is an output waveform diagram displayed on an oscilloscope when characteristic impedance according to the laminated structure of the 2-layer PCB shown in FIG. 3 is 160Ω;

FIG. 5 is a view showing a laminated structure of a 2-layer PCB according to a preferred embodiment of the present invention;

FIG. 6 is an output waveform diagram displayed on an oscilloscope when characteristic impedance according to the laminated structure of the 2-layer PCB shown in FIG. 5 is 50Ω; and

FIG. 7 is a view illustrating a flow of manufacturing the 2-layer PCB according to the preferred embodiment of the present invention.

### DETAILED DESCRIPTION OF THE INVENTION

Hereinafter, a preferred embodiment of a 2-layer printed circuit board (PCB) and a method of manufacturing the same according to the present invention will be described in detail with reference to the accompanying drawings.

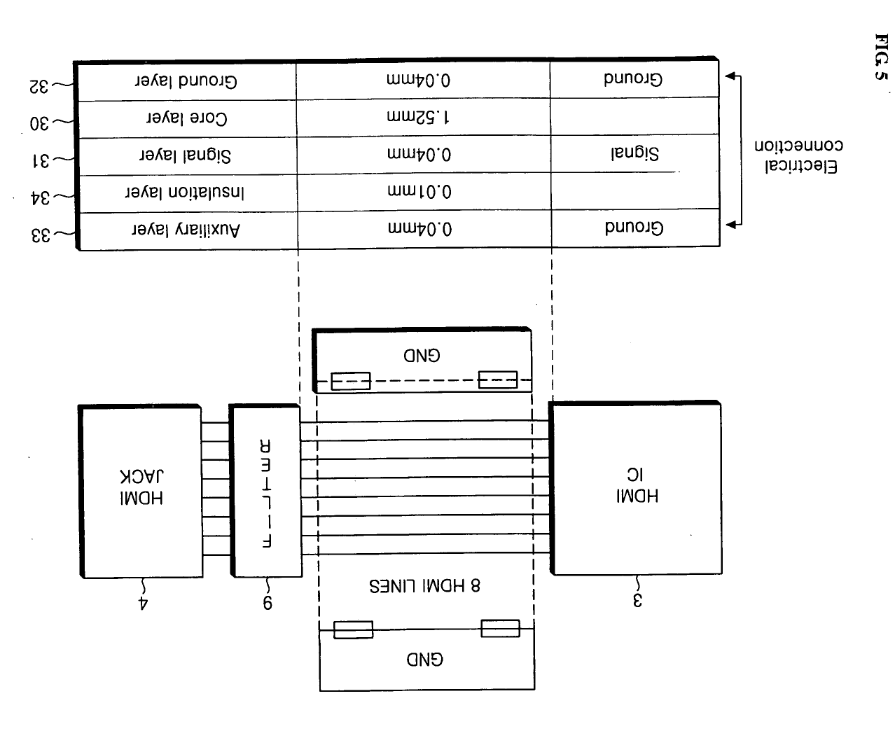

First, a laminated structure of a 2-layer PCB according to a preferred embodiment of the present invention will be described with reference to FIG. 5. In the description of the 2-layer PCB that is the embodiment of the present invention, it will be applied to the configuration of the DVD/recorder and the TV device, which have described in the related art, and like elements are designated by like reference numerals.

As shown in this figure, in the laminated structure of the 2-layer PCB, a signal layer 31 provided with a signal line for transmitting a high frequency signal and a ground layer 32 for echoing/shielding/heat dissipating operation of a transmission signal are formed on top and bottom surfaces of a core layer 30, respectively. The signal layer 31 is made of a copper clad laminated plate (not shown) such that a high frequency signal line can be formed. The copper clad laminated plate is two or more sheets of copper foil integrally adhered to each other. Here, the core layer 30 is set to have a thickness of 1.52 mm, the signal layer 31 is set to have a thickness of 0.04 mm, and the core layer 30 is also set to have a thickness of 0.04 mm.

An insulation layer 34 with a certain thickness which serves as insulation of a printed wiring board is formed on a top surface of the signal layer 31. It is preferred that the insulation layer 34 have a thickness of 0.01 mm when the core, signal and ground layers 30, 31 and 32 respectively have the aforementioned thicknesses.

An auxiliary layer 33 formed only in the high frequency signal line, which is formed on the signal layer 31 for impedance matching, is formed on a top surface of the insulation layer 34. It is preferred that the auxiliary layer 33 be formed to have a thickness of 0.04 mm. The auxiliary layer 33 may be formed to be identical with a high frequency signal line pattern or to have a region slightly broader than the high frequency signal line pattern. The high frequency signal line formed on the signal line 31 includes a line through which not only video and audio signals but also general control signals are transmitted. A high frequency of the PCB in accordance with a frequency is a time point when signal distortion is not generated only if a control operation such as impedance matching should be performed. Thus, a transmission rate through the high frequency signal line is generally 166 MHz or more. At this time, unless the impedance matching is performed, waveform distortion is generated, whereby system malfunction is caused. In a case where the transmission rate through the high frequency signal line is 166 MHz or less, waveform distortion or the like is not generated although a control process such as impedance matching is not performed.

The auxiliary layer 33 is electrically connected to the ground layer 32, so that the auxiliary layer 33 serves as a ground plane. When the auxiliary layer 33 serves as a ground plane, it provides an effect that the ground plane approaches onto the high frequency signal line of the signal layer 31. Thus, it is possible to solve the problem that impedance is not matched since the thickness of the core layer formed between the signal and ground layers in the conventional 2-layer PCB structure cannot but be formed to be 1.52 mm or more. In other words, if the auxiliary layer 33 that is electrically connected to the ground layer 32 and serves as the ground plane is formed over the top surface of the signal layer 31, there can be provided an impedance value lower than that when the thickness of the core layer is 1.52 mm or more. When the impedance value is decreased as described above and then a characteristic impedance value becomes 50Ω, there is provided an effect that a distance between the signal and ground layers 31 and 32 can be preferably maintained to be approximately 0.35 mm.

The auxiliary and ground layers 33 and 32 are electrically connected to each other with a conductor component using via holes formed in predetermined portions of the core, signal and insulation layers 30, 31 and 34.

The auxiliary layer 33 may be a liquefied carbon substance applied in a PCB manufacturing process, a PCB, or a tape in the form of copper foil. Further, the thickness of the insulation layer 34 varies depending on the kind of substance for forming the auxiliary layer 33. If the auxiliary layer 33 is the coated, liquefied carbon substance, the thickness of the insulation layer 34 also varies. For example, in a case where the auxiliary layer 33 is applied to be 0.04 mm in thickness, a characteristic impedance of 50Ω can be provided when the insulation layer 34 has a thickness of 0.01 mm. Further, the thickness of the insulation layer 34 is determined to be different depending on a characteristic impedance value of the high frequency signal line.

As such, if the PCB composed of the core, signal, ground, auxiliary and insulation layers 30, 31, 32, 33 and 34 is formed to be provided between the HDMI IC 3 and the HDMI jack 4 for transmission, the video and audio signals and the like that are processed in the HDMI IC 3 through the high frequency signal line formed on the signal line 31 are output to the TV 5 through the HDMI jack 4.

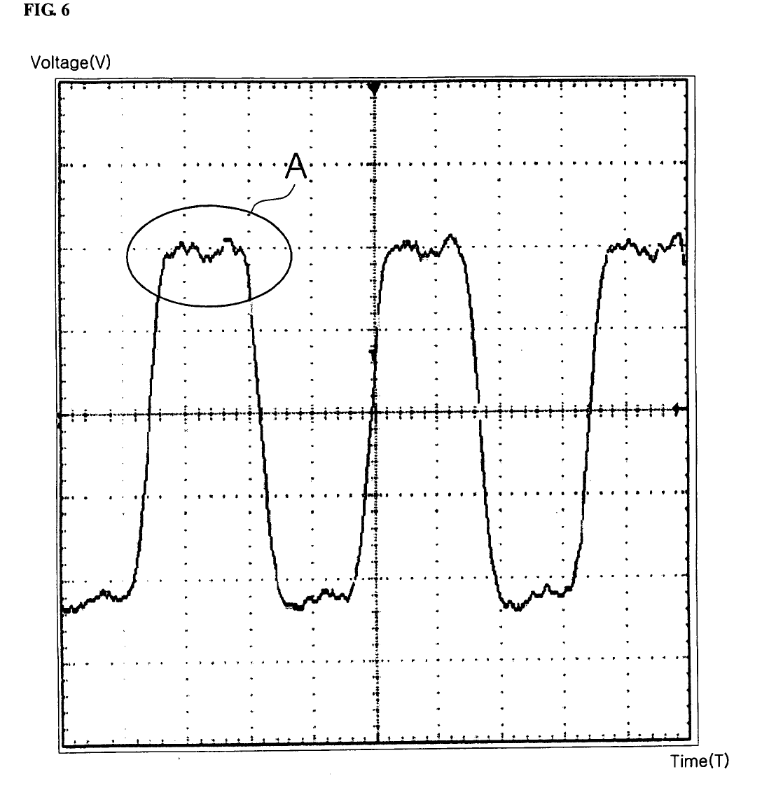

Next, FIG. 6 illustrates an output waveform diagram displayed on an oscilloscope when characteristic impedance according to the laminated structure of the 2-layer PCB of the present invention is 50Ω. The waveform diagram is an embodiment in which a voltage (V) state is output as time (T) elapses.

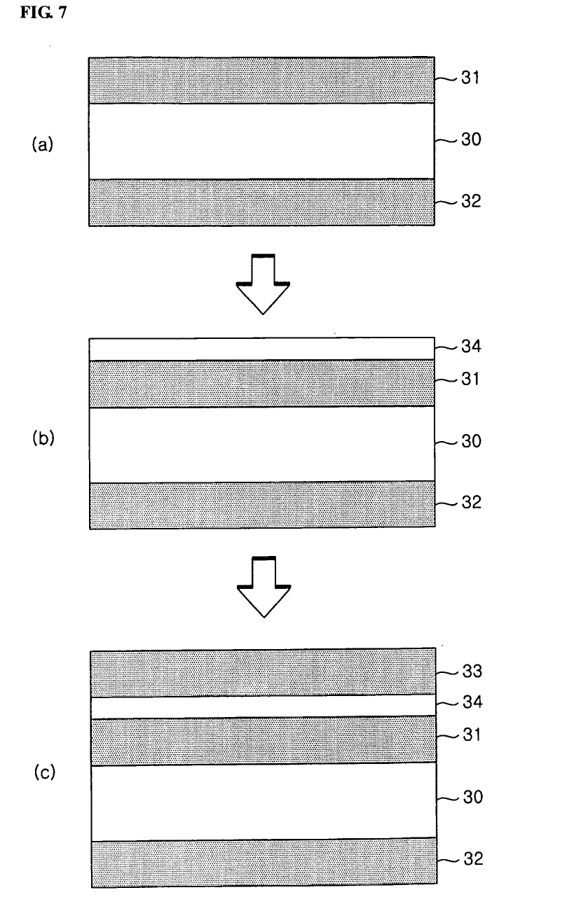

Further, FIG. 7 illustrates an operational state of manufacturing the 2-layer PCB according to the preferred embodiment of the present invention. FIG. 7 schematically shows the order in which the core, signal, ground, auxiliary and insulation layers 30, 31, 32, 33 and 34 are laminated in order and formed. Although the auxiliary layer 33 should be electrically connected to the ground layer 32 in this figure, its connection configuration is not shown. The connection is effected using via holes (not shown) to connect circuits in respective layers. The via hole is a structure generally used in a PCB, and detailed descriptions thereon will be omitted.

Meanwhile, the structure of the core, signal and ground layers 30, 31 and 32, which is shown in FIG. 7 (a), may be applied to a general 2-layer PCB, or the layers 30, 31 and 32 may be sequentially formed from the beginning. However, since the thickness of each of the layers has been already determined to be provided even in both the cases, the provided thickness value should be applied in a case where the layers 30, 31 and 32 are sequentially formed. It is noted that if the thickness value is not applied and the layers 30, 31 and 32 are formed, the auxiliary and insulation layers 33 and 34 which will be subsequently formed should be also modified as a thickness making characteristic impedance matching possible.

Subsequently, a method of manufacturing the PCB having the aforementioned structure according to the present invention will be described with reference to FIGS. 5 to 7.

First, a copper clad laminated (CCL) plate, in which 2 or more sheets are integrally adhered, is attached on a top surface of the core layer 30 so as to form a conductor pattern. In order to remove foreign substances on a surface of the CCL plate, face machining for grinding the surface with a brush to flatten it is performed

Further, an etching process is performed after general light-exposing and developing processes, and then, high frequency signal and ground lines are designed on the CCL plate to form the signal layer 31 and to form the ground layer 32 on a bottom surface of the core layer 30 (FIG. 7 (a)). The signal and ground layers 31 and 32 may be simultaneously formed, or any one layer thereof may be formed first. The signal layer 31 is formed on the top surface of the core layer 30, and the ground layer 32 is formed on the bottom surface thereof.

If a high frequency signal line is formed in the signal layer 31, the insulation layer 34 is formed by applying a solder resist with an insulative property onto a top surface of the signal line 31 so as to protect the high frequency signal line and provide an insulating function (FIG. 7 (b)).

In order to provide impedance matching in the PCB having the 2-layer laminated structure, the thickness of the insulation layer 34 is determined depending on the kind of the auxiliary layer 33 provided on the top surface of the insulation layer 34.

That is, after the insulation layer 34 is formed, the auxiliary layer 33 is formed on the top surface of the insulation layer 34 (FIG. 7 (c)). At this time, in a case where the auxiliary layer 33 is a liquefied carbon substance applied onto the insulation layer 34, the thickness of the insulation layer 34 should be maintained to be 0.01 mm. If a PCB or a tape in the form of copper foil is used as the auxiliary layer 33, the thickness of the auxiliary layer 33 should be determined to be different from that determined when the liquefied carbon substance is applied.

Here, the liquefied carbon substance, the PCB, or the tape in the form of copper foil should be provided only in a specific high-frequency signal line region which is formed in the signal layer 31 for impedance matching of the high frequency signal line.

Also, the thickness of the auxiliary layer 33 may vary depending on a characteristic impedance value of the high frequency signal line. For example, although general characteristic impedance is currently set with 50Ω as a reference, the thickness of the insulation layer 34 should be modified in a case where the characteristic impedance is required to have a different value. It will be apparent that the thickness of the insulation layer 34 should be determined keeping pace with the kind of substance provided to the auxiliary layer 33.

In a state where the insulation layer 34 of which the thickness has been determined and the auxiliary layer 33 for impedance matching are formed on the top of the signal layer 31, the auxiliary layer 33 is electrically connected to the ground layer 32. If the auxiliary and ground layers 33 and 32 are electrically connected to each other, the auxiliary layer 33 serves as a ground plane. Accordingly, there is provided the effect that the ground plane approaches onto the high frequency signal line of the signal layer 31, so that the impedance matching is possible.

In other words, although a space between the signal and ground layers 31 and 32 should be maintained to be 0.35 mm so as to match the characteristic impedance of 50Ω in the 2-layer PCB, the space of 0.35 mm cannot be maintained due to the physical structure of the 2-layer PCB. However, if the auxiliary layer 33 is laminated and formed over the signal layer 31 and electrically connected to the ground layer 32, the auxiliary layer 33 serves as a ground plane and thus provides an operation that the space of 0.35 mm is substantially maintained.

If the liquefied carbon substance, the PCB, the tape in the form of copper foil or the like is additionally provided in the PCB having such a 2-layer laminated structure, the impedance matching that is impossible in the 2-layer PCB becomes possible, and thus, the generation of signal distortion is prevented when uncompressed full digital audio/video signals are transmitted through the high frequency signal line.

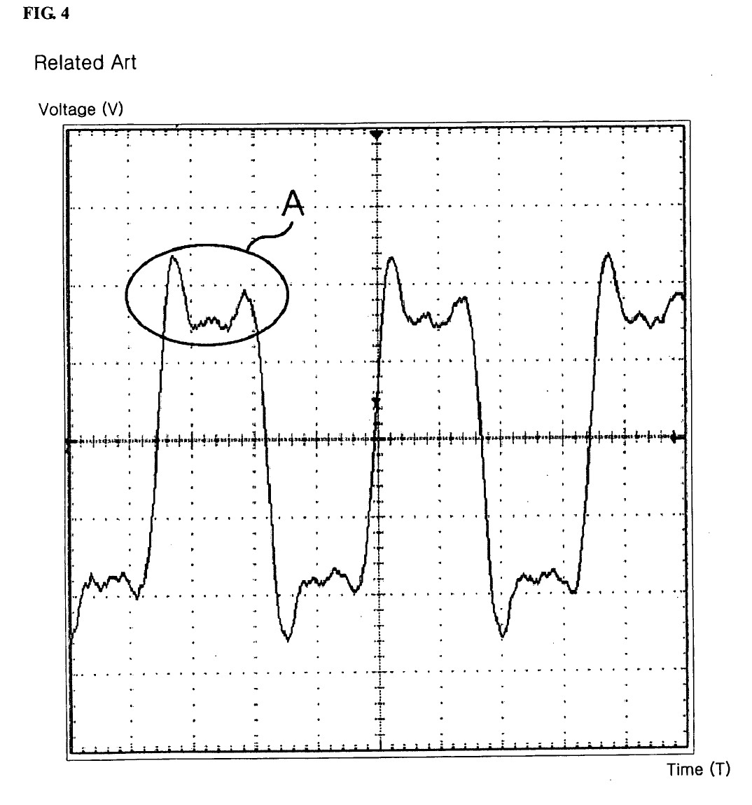

Referring to FIG. 6 illustrating an output waveform diagram displayed on an oscilloscope when the impedance matching is performed with the characteristic impedance according to the laminated structure of the 2-layer PCB being 50Ω, the aforementioned signal distortion phenomenon shown in portion “A” of FIG. 4 does not appear.

As such, in the present invention, which has been described in the embodiment, an auxiliary layer such as a liquefied carbon substance, a PCB, or a tape in the form of copper foil is additionally provided to a 2-layer PCB, and the auxiliary layer is electrically connected to a ground layer for the auxiliary layer to be used as a ground plane, whereby the 2-layer PCB possible for impedance matching can be provided.

As described in detail above, in a 2-layer PCB and a method of manufacturing the same according to the present invention, the following advantages can be expected.

There is an advantage in that if an auxiliary layer is provided on a signal layer and the ground and auxiliary layers are electrically connected for the auxiliary layer to be used as a ground plane in the 2-layer PCB, a space between the signal and ground layers can be maintained to be 0.35 mm, which is a physical space in which a characteristic impedance of 50Ω can be provided. Thus, impedance matching of a high frequency signal line becomes possible even in a 2-layer PCB.

Further, the manufacturing costs can be reduced by simplifying a laminated structure, whereby the superiority of competitive power can be expected.

Although the present invention has been described in connection with the preferred embodiment, the embodiment of the present invention is only for illustrative purposes. It will be apparent that those skilled in the art can make various modifications, changes and other equivalent embodiments thereto without departing from the spirit and scope of the invention. Therefore, the true scope of the present invention should be defined by the technical spirit of the appended claims.

What is claimed is:

1. A 2-layer printed circuit board (PCB), comprising:
a core layer made of insulator;
a signal layer formed on a top surface of the core layer and provided with a high frequency signal line;
a ground layer formed on a bottom surface of the core layer;
an insulation layer formed in a predetermined thickness on a top surface of the signal layer; and
an auxiliary layer formed on a top surface of the insulation layer for impedance matching of the high frequency signal line provided in the signal layer, the auxiliary layer being electrically connected to the ground layer.

2. The 2-layer PCB as claimed in claim 1, wherein the thickness of the insulation layer is determined depending on the kind of substance constituting the auxiliary layer.

3. The 2-layer PCB as claimed in claim 1, wherein the thickness of the insulation layer is determined depending on characteristic impedance of the high frequency signal line.

4. The 2-layer PCB as claimed in claim 3, wherein the characteristic impedance is 50Ω.

5. The 2-layer PCB as claimed in claim 1, wherein the auxiliary layer is formed only in a region of the high frequency signal line.

6. The 2-layer PCB as claimed in claim 5, wherein the auxiliary layer is any one of a liquefied carbon substance, a PCB, and a tape in the form of copper foil.

7. The 2-layer PCB as claimed in claim 2 or 6, wherein the thickness of the insulation layer is 0.01 mm in a case where the auxiliary layer is a liquefied carbon substance.

8. The 2-layer PCB as claimed in claim 1, wherein the insulation layer is a liquefied solder resist.

9. A method of manufacturing a 2-layer PCB, comprising:
forming a signal layer provided with a high frequency signal line and a ground layer serving as a ground on top and bottom surfaces of a core layer made of an insulator, respectively;
forming an insulation layer on a top surface of the signal layer;
forming an auxiliary layer on a top surface of the insulation layer; and
connecting the auxiliary and ground layers electrically to each other,
wherein the auxiliary layer is formed only in a region of the high frequency signal line provided in the signal layer.

10. The method as claimed in claim 9, wherein the thickness of the insulation layer is determined depending on the kind of substance constituting the auxiliary layer.

11. The method as claimed in claim 9, wherein the thickness of the insulation layer is determined depending on a characteristic impedance value of the high frequency signal line.

12. The method as claimed in claim 11, wherein the characteristic impedance value is variable.

13. The method as claimed in claim 9, wherein the auxiliary layer is formed by applying a liquefied carbon substance.

14. The method as claimed in claim 9, wherein the auxiliary layer is formed by seating a PCB.

15. The method as claimed in claim 9, wherein the auxiliary layer is formed by attaching a tape in the form of copper foil.

16. The method as claimed in claim 10 or 13, wherein the insulation layer is formed to have a thickness of 0.01 mm when the auxiliary layer is made of a liquefied carbon substance and has a thickness of 0.04 mm.

17. The method as claimed in claim 9, wherein a liquefied solder resist with an insulative property is applied on the insulation layer.
